(19) United States
(12) Patent Application Publication
(10) Pub. No.: US 2022/0262972 A1
(43) Pub. Date: Aug. 18, 2022

(54) SYSTEMS AND METHODS FOR A MULTI-USE RURAL LAND SOLAR MODULE

(71) Applicants: Christiana Honsberg, Tempe, AZ (US); Stuart Bowden, Tempe, AZ (US)

(72) Inventors: Christiana Honsberg, Tempe, AZ (US); Stuart Bowden, Tempe, AZ (US)

(21) Appl. No.: 17/626,432

(22) PCT Filed: Jul. 13, 2020
(86) PCT No.: PCT/US2020/041828

§ 371 Date: Jan. 11, 2022

Related U.S. Application Data
(60) Provisional application No. 62/873,282, filed on Jul. 12, 2019.

(51) Int. Cl. H01L 31/054; H01L 31/048; H01L 31/0236

(52) U.S. Cl. CPC H01L 31/0547; H01L 31/0236; H01L 31/048

(57) ABSTRACT

Various embodiments of systems and methods for a solar module which concentrates light onto a solar cell while allowing diffuse light to pass to below crops are disclosed.

### CROSS REFERENCE TO RELATED APPLICATIONS

This is a PCT international application that claims benefit to U.S. provisional application Ser. No. 62/873,282 filed on Jul. 12, 2019, which is herein incorporated by reference in its entirety.

### GOVERNMENT SUPPORT

This invention was made with government support under grant number 1041895 awarded by the National Science Foundation. The Government has certain rights in the invention.

### FIELD

The present disclosure generally relates to photovoltaics; and in particular, to a multi-use solar module with integrated photovoltaics for concentrating light on solar cells and allowing diffuse light to pass through to facilitate the growth of crops under a solar array.

### BACKGROUND

Over the last decade, photovoltaics have dramatically altered the electricity landscape, evolving from a critical driver of high value applications (e.g. satellites for aircraft navigation, remote power) to a significant electricity source. Photovoltaics provide a lower levelized cost of electricity than any other electricity generating source. The developing use of photovoltaics in agriculture (agrivoltaics) leverages photovoltaics to provide multiple advantages, including an electricity load that is both high and well-matched to the solar radiation profile. For greenhouses, photovoltaics have also been utilized as a shading element.

Previously, projects focused on photovoltaics have been sited on raw unused land located in remote locations near utility lines. Because some of these projects have damaged sensitive ecosystems, they receive scrutiny and are required to complete detailed environmental impact studies, which are expensive and require a long time to process. In order to speed up projects, developers have moved away from utilizing raw land and have instead started to develop projects on farm land. Having been tilled, the land no longer contains sensitive ecosystems that require protection. Farmers have been willing to convert their land to solar generation of electricity because this provides a greater profit than farming. Unfortunately, that has caused a new challenge which is the loss of usable farmland. Municipalities across the country are enacting legislation to protect farm land from solar development to protect this resource.

In recent years, installing solar panels on rooftops has become fashionable. Unfortunately, this solution alone cannot meet the need for renewable energy. A 2015 NREL and DOE report estimates that nearly 50% of consumers and businesses are unable to host photovoltaic systems. Further, residential solar arrays can cause challenges in load balancing for utility systems. Therefore, in order to address this unmet need, the market size for agrivoltaic products is greater than half of the potential market for photovoltaics. Community solar and utility-scale projects are the only solution to provide renewable energy to this unserved population.

It is with these observations in mind, among others, that various aspects of the present disclosure were conceived and developed.

### BRIEF DESCRIPTION OF THE DRAWINGS

FIG. 1 is an illustration showing a photovoltaic (PV) unit which redirects light towards a photovoltaic cell while allowing diffuse light to pass through using an optical film;

FIG. 2 is a diagram showing light steering properties of the PV unit of FIG. 1,

FIG. 3 is a diagram showing light steering properties of the PV unit of FIG. 1 including the redirection of incident light through an optical element and towards a photovoltaic cell;

FIG. 4 is a photograph showing the PV unit of FIG. 1 with holographic optical element;

FIG. 5 is a graph showing power production for each fixed half-tilt value (15, 30 and 45 degrees) across a plurality of panel tilt values for the PV unit of FIG. 1 as taken from a Los Angeles facility;

FIG. 6 is a graph showing light transmittance of the optical element of FIG. 4 across wavelengths; and

FIG. 7 is a photograph showing a bifacial photovoltaic cell for use with the PV unit of FIG. 1.

Corresponding reference characters indicate corresponding elements among the view of the drawings. The headings used in the figures do not limit the scope of the claims.

### DETAILED DESCRIPTION

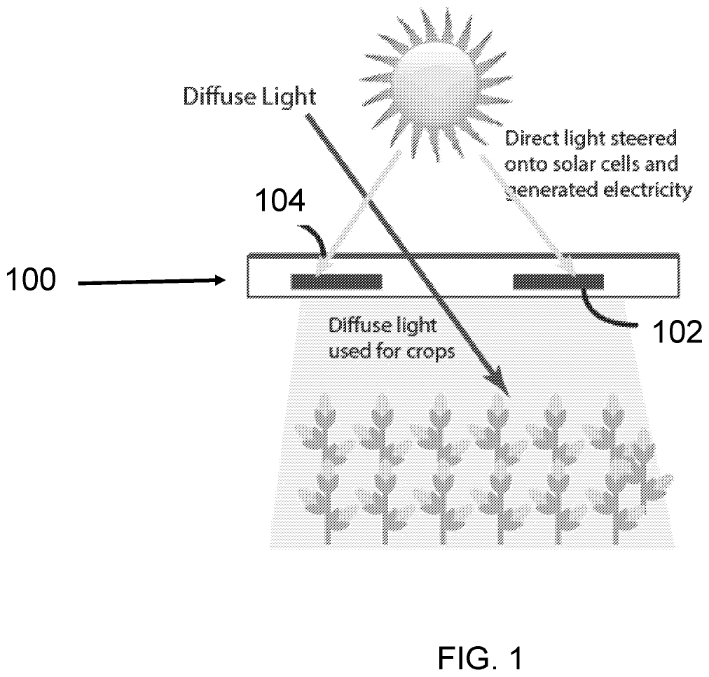

Various embodiments of a photovoltaic (PV) unit which re-directs light such that light is concentrated on a photovoltaic (PV) cell while allowing the passage of diffuse light are disclosed herein. In some embodiments, the PV unit includes a transparent substrate with photovoltaic cells embedded within. The PV unit may also include an optical element for redirecting light towards the PV cell, while allowing diffuse light of certain wavelengths to pass through the PV unit and down to crops underneath the PV unit. In some embodiments, the optical element of the PV unit may have holographic properties. Referring to the drawings, embodiments of a PV unit are illustrated and generally indicated as 100 in FIGS. 1-7.

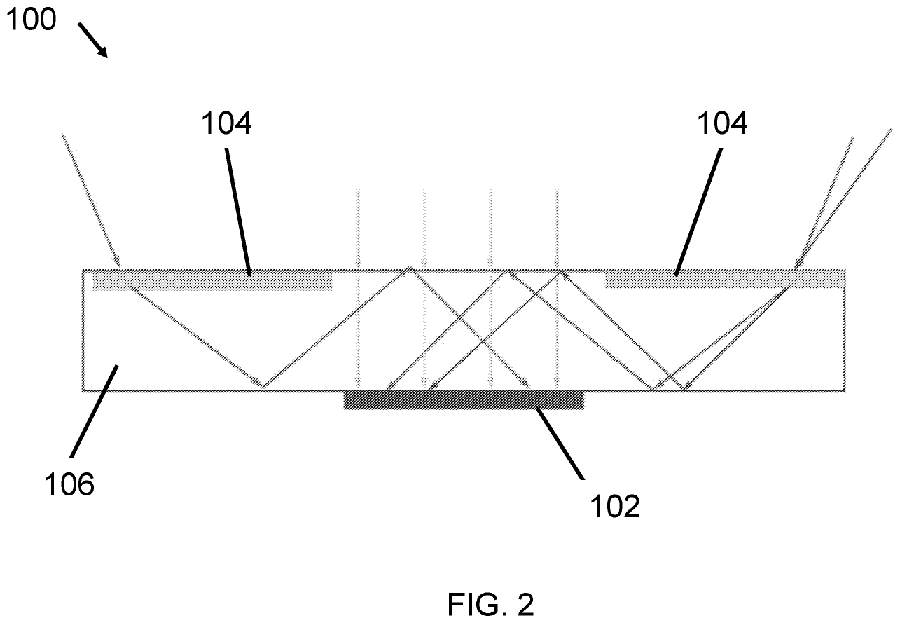

Referring to FIGS. 1 and 2, a PV unit 100 is shown which includes a PV cell 102 and one or more strips of optical element 104 along a transparent substrate 106. As light passes through the PV unit 100, the light is sorted and redirected by the optical element 104 such that light is concentrated on the PV cell 102, thus increasing the amount of electricity generated by the PV cell 102. Further, in some embodiments, the optical element 104 allows wavelengths of light which contribute to photosynthesis to pass through the PV unit 100 as diffuse light, so that plants located beneath the PV unit 100 can still receive that diffused light. FIG. 1 shows one application where the PV unit 100 allows farmland to be simultaneously used for growing crops and facilitating energy generation.

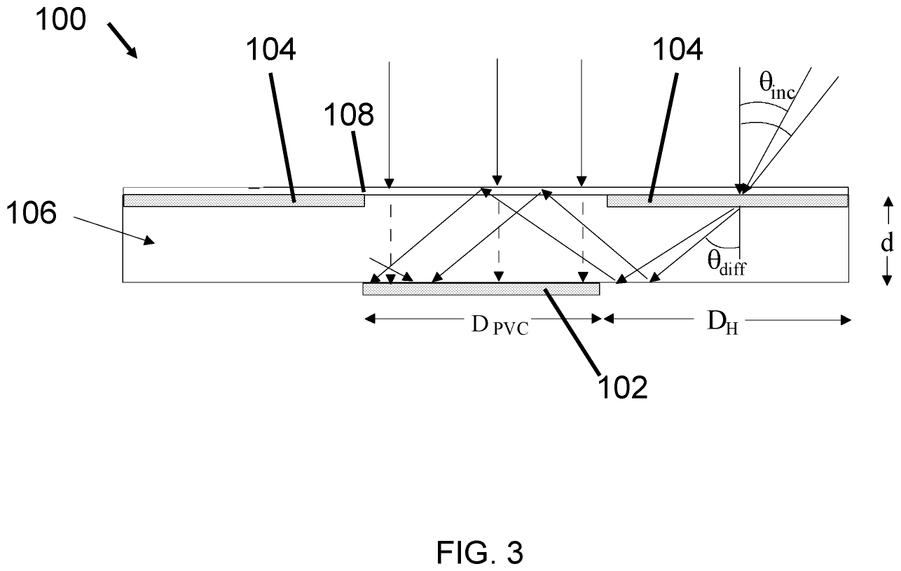

Referring to FIGS. 2 and 3, the PV unit 100 may include one or more strips of optical element 104 embedded within the substrate 106. As shown, the optical element 104 is located on or within an upper surface 162 of the substrate 106 so as to direct light towards the PV cell 102, which is located near a lower surface 164 of the substrate 106. Referring to FIG. 3, the optical element 104 provides a low-optical concentration of direct light onto the PV cell 102 while allowing diffuse light to pass through. Direct radiation from the sun may be directed towards the PV cell 102 for diffusing radiation, which does not contact the PV cell 102, and may pass through the PV unit 100. An amount of direct light on the PV cells 102 may be readily altered by either moving the optical element 104 to a different location within the substrate 106 to alter an acceptance angle or by changing a tilt angle of the PV unit 100 as a whole. In some embodiments, the PV unit 100 may be encapsulated in a glass or otherwise transparent encapsulation 108 to provide protection for the optical element 104 and the PV cell 102 against outdoor elements including dirt, dust, water, and animal droppings.

The optics operation of the PV unit 100 is illustrated in FIGS. 2 and 3. The optical element 104 may change an angle θ_{inc} of incident light such that the total internal reflection causes the PV unit 100 to act as a waveguide, thereby directing light at a new angle θ_{diff} towards the PV cell 102. Depending on holographic properties of the optical element 104, optical concentration causes light intensity on the PV cell 102 to be 2 to 8 times that of the incident light on the upper surface 162. Further, in some embodiments, the optical element 104 may be wavelength-selective, thereby allowing light which is most beneficial for plants to pass through the PV unit 102.

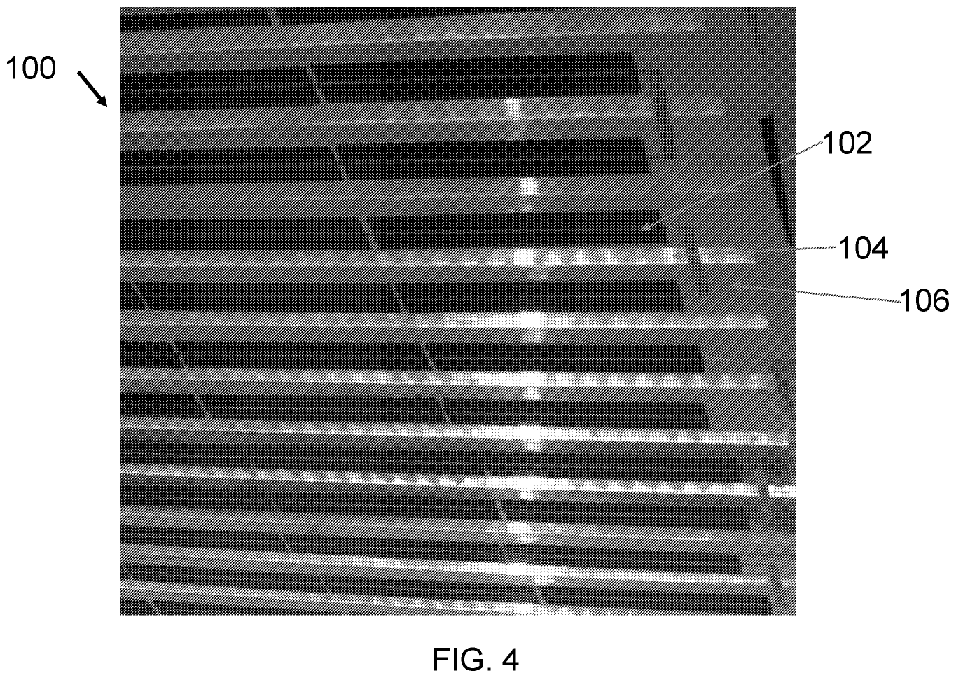

A central innovation in the PV unit 100 is the development of the optical element 104 which steers direct light towards the solar cell 102 while diffuse light is allowed to pass through the PV unit 100. In some embodiments, the optical element 104 may embody a static or non-imaging concentrator. In one aspect, the central trade-off in the design of non-imaging optical systems is their acceptance angle and maximum allowable concentration, governed by the principles of étendue (which characterizes how “spread out” the light is in terms of area and angle). A given concentration level limits the acceptance angle of the optical system. High concentration systems have an acceptance angle of a degree or less, and hence require two-axis tracking to keep the PV unit 100 pointed towards the sun. Diffuse light from sun is outside the acceptance angle of the high concentrating system, and is not directed towards the PV cell 102. A low concentration has a larger angle of acceptance, but some light from the sun does not reach the PV cell 102. In a typical low concentration system, this light is a loss, but in the present semitransparent system embodied by the PV unit 100, this light passes through the PV unit 100 and may expose crops or plants located underneath the PV unit 100. The optical element 104 can be implemented in a number of ways, including slats or aligned texturing of the optical element 104 and may, in some embodiments, include holographic elements, as shown in FIG. 4.

Referring directly to FIG. 4, in some embodiments the optical element 104 may be a holographic film. The holographic film may be integrated into the PV unit 100 without increasing the thickness of the unit 100, and in some embodiments is spectrally tuned so certain wavelengths which are beneficial for photosynthesis can reach any crops or plants below.

There are several critical parameters of the optical film 104 which impact the performance of the overall system. These include the area of the PV unit 100 covered by PV cells 102 compared to its total area (the geometric concentration ratio) and the ratio between the intensity of incident light on the PV unit 100 and incident light on the PV cells 102. These two ratios are not the same due to reflection of light at the upper surface 162 of the PV unit 100, absorption in the optical element 104, and light not directed to the PV cells 102 but rather passing through the PV unit 100. In a conventional static concentrator, light not directed to the PV cell 102 is a loss; in the present semitransparent PV unit 100, this is not a loss, but rather an integral feature that lets light pass through to the crops or plants located below the PV unit 100. Some direct light which is outside the acceptance angle of the PV unit 100 will also pass through the PV unit 100. A key trade-off is how much light is redirected to the PV cells 102 and how much passes through the PV unit 100. An important note is that this amount can be adjusted by changing a tilt angle of the PV unit 100 or by adjusting an acceptance angle (and hence the concentration of the system).

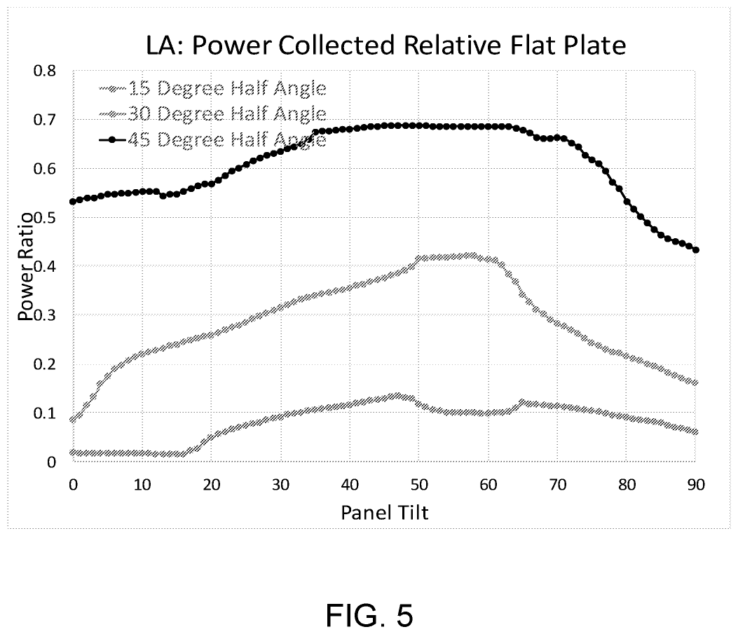

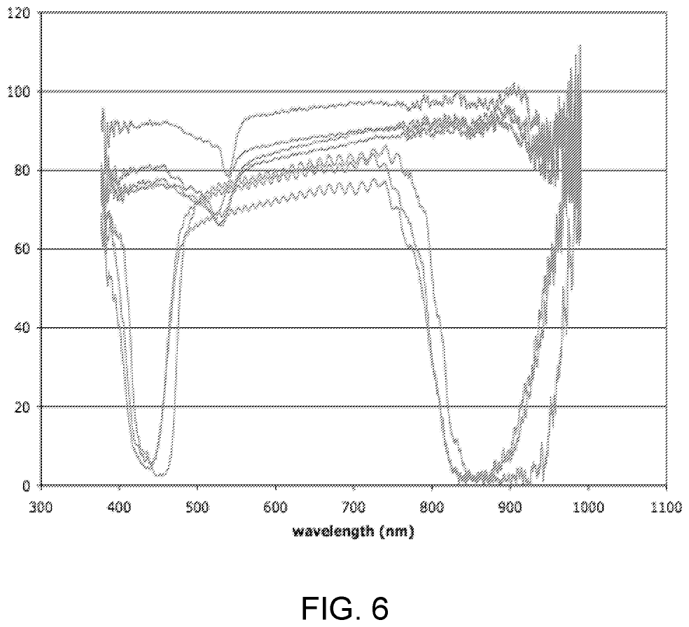

For example, FIG. 5 shows initial calculations for Los Angeles Calif. using TMY data from the National Radiation Database maintained by the National Renewable Energy Laboratory. The TMY data has measured values of direct and diffuse radiation for every hour of the year. A 45° half-angle acceptance has a concentration (excluding horizon band light) of approximately 2×; the 15° half angle has approximately 5× concentration. Light coming from a band around the horizon of 10° may be excluded from consideration since PV systems typically do not “see” the horizon as they are blocked by buildings, trees, or other PV modules. The results show that with a small half angle, a relatively small amount of light is collected by the solar panels, but there are also fewer solar cells in the solar panel (⅕ of the area is solar cells). The differing amount of electricity generated compared to light passing to the crops and the economic optimum depends on the location, the value of the crop land and the crops grown, and the amount of light needed by the crops. Referring to FIG. 6, one particular embodiment of the holographic optical unit 104 does not direct light from the near-UV and near-infrared wavelengths to the PV cell 102, but instead allows the visible portions to pass. This can be adjusted to reject parts of the spectrum to the optimum wavelengths for crops, which tend to reject light in the 500 nm range (hence their green color).

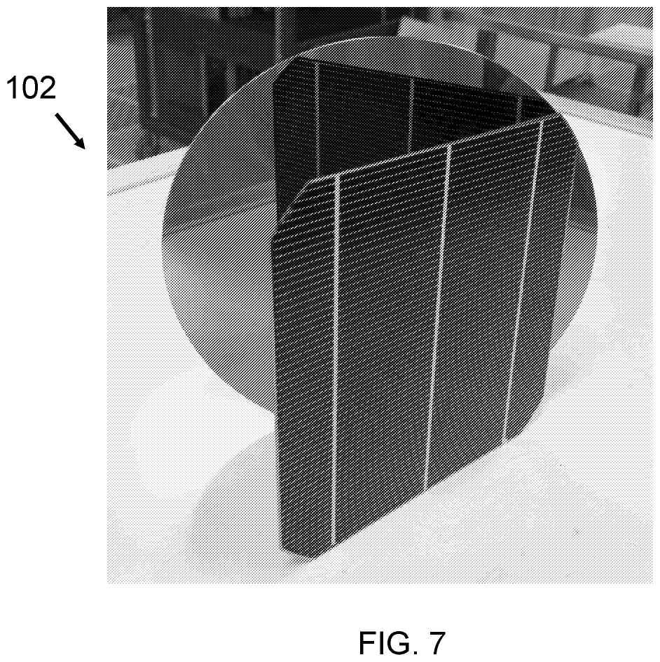

In some embodiments, the PV cells 102 are bifacial in order to maximize energy output from the PV unit 100. The semitransparent PV unit 100 may inherently use a glass/glass encapsulation (or other transparent front and back sheets). In the semi-transparent module, the glass/glass encapsulation allows for the use of bifacial cells. A bifacial PV cell 102, as shown in FIG. 7, responds to light from both the front and the back, such that the PV unit 100 would absorb light reflected from the crop back onto the PV unit 100. Crops and grass have been measured as having an albedo of 25%. Thus, a solar cell with a high bifaciality ratio (the response from the rear compared to the response of light from the front) would increase the energy from the module, with the exact fraction depending on the optical design and the angle of the reflected light. Solar cells with high bifaciality ratios tend to be thinner, high performance solar cells.

Another embodiment of the PV unit 100 uses all-back contact solar cells. This type of semi-transparent PV unit 100 is unique in that the low concentration reduces the area of the PV cells 102, thus enabling the use high performance cells while still realizing a lower cost module. Silicon heterojunction solar cells with back contact have shown over 26% efficiency and presently hold the silicon efficiency record. Because there is no metal reflection on the front surface, such solar cells have higher efficiency for front illumination. Although they may have some response from light incident on the rear, the higher fraction of metal on the rear make the rear response poor. The trade-off is that light incident on the front will have a higher efficiency, but light incident on the rear will be essentially rejected.

In another embodiment of the PV unit 100, the PV cell 102 may include front-surface texturing. A PV cell 102 in a static concentrator configuration will have a higher portion of light incident on the PV cell 102 at angles further away from normal. Conventional front surface structures are designed primarily for light incident and angles close to normal to the surface of the PV cell 102. Conventional front surface texturing comprising a plurality of upright pyramids is formed by crystallographic etching, and hence the angle of the pyramids is not fixed. In another embodiment, the PV cells 102 may include nanostructured texturing (“black silicon”) to improve front surface reflection.

A key advantage of the present PV unit 100 is that the low concentration system allows high efficiency PV cells, which helps maintain the electrical output of a PV array comprised of a plurality of PV units 100 even as diffuse light is directed to the crops below the module. The PV cells 102 impact the overall module design in multiple ways, from the size to the architecture of the solar cells 102.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A photovoltaic unit, comprising:
a substrate defining an upper surface and a lower surface;
a photovoltaic cell defined on or above the lower surface of the substrate; and
one or more optical elements defined on or below the upper surface of the substrate;
wherein the one or more optical elements are operable for redirecting a first portion of incident light towards the photovoltaic cell; and
wherein the one or more optical elements are operable for allowing a second portion of incident light to pass through the one or more optical elements and the substrate.

2. The photovoltaic unit of claim 1, wherein the substrate is a transparent material.

3. The photovoltaic unit of claim 1, wherein the first portion of incident light is concentrated onto the photovoltaic cell by the optical element.

4. The photovoltaic unit of claim 3, wherein the photovoltaic unit comprises a low concentration system.

5. The photovoltaic unit of claim 1, wherein the second portion of incident light is passed through the photovoltaic unit as diffuse light.

6. The photovoltaic unit of claim 1, wherein the plurality of optical elements are wavelength-selective such that the diffuse light comprises select wavelengths of light.

7. The photovoltaic unit of claim 6, wherein the select wavelengths of light comprise one or more wavelengths which promote photosynthesis.

8. The photovoltaic unit of claim 1, wherein an amount of light directed towards the photovoltaic cell is increased or decreased by increasing or decreasing an acceptance angle defined by the one or more optical elements.

9. The photovoltaic unit of claim 8, wherein the acceptance angle is altered by altering a position of the optical element relative to the photovoltaic cell.

10. The photovoltaic unit of claim 1, wherein an amount of light directed towards the photovoltaic cell is increased or decreased by altering a tilt angle of the unit.

11. The photovoltaic unit of claim 1, wherein the optical element is a static concentrator.

12. The photovoltaic unit of claim 1, wherein the optical element is a non-imaging concentrator.

13. The photovoltaic unit of claim 1, wherein the optical element comprises front surface texturing.

14. The photovoltaic unit of claim 13, wherein the front surface texturing is nanostructured texturing.

15. The photovoltaic unit of claim 1, wherein the optical element comprises a holographic film.

16. The photovoltaic unit of claim 1, wherein the photovoltaic cell is bifacial.

17. The photovoltaic unit of claim 1, wherein the photovoltaic cell is an all-back contact photovoltaic cell.

18. The photovoltaic unit of claim 1, wherein the photovoltaic unit further includes a transparent encapsulation.
